(19) United States
(12) Patent Application Publication
(10) Pub. No.: US 2025/0185427 A1
(43) Pub. Date: Jun. 5, 2025

(54) METHOD FOR MANUFACTURING LIGHT-EMITTING DEVICE

(71) Applicant: NICHIA CORPORATION, Tokushima-shi (JP)

(72) Inventor: Kota OKURA, Anan-shi (JP)

(73) Assignee: NICHIA CORPORATION, Tokushima-shi (JP)

(21) Appl. No.: 18/960,735

(22) Filed: Nov. 26, 2024

(30) Foreign Application Priority Data
Nov. 30, 2023 (JP) 2023-202973

(51) Int. Cl. H01L 33/54; H01L 33/60

(52) U.S. Cl. CPC H10H 20/853; H10H 20/856; H10H 20/0362; H10H 20/0363

(57) ABSTRACT

A method for manufacturing a light-emitting device includes disposing a plurality of light-emitting elements on a support, each of the plurality of light emitting elements having an upper surface; disposing on the upper surfaces of the light-emitting elements and between adjacent light-emitting elements of the plurality of light-emitting elements an inorganic member having a void; forming a groove between the adjacent light-emitting elements in the inorganic member, and disposing a covering member on an upper surface of the inorganic member located above the light-emitting elements and in the groove to impregnate the void with a part of the covering member.

### CROSS-REFERENCE TO RELATED APPLICATION

This application claims priority to Japanese Patent Application No. 2023-202973 filed on Nov. 30, 2023, the disclosure of which is hereby incorporated by reference in its entirety.

### BACKGROUND

### Technical Field

The present disclosure relates to a method for manufacturing a light-emitting device.

### Background Art

A light-emitting device including a light-emitting element and a covering member formed of an inorganic member and covering a part of the light-emitting element is known (for example, see JP 2022-58212).

### SUMMARY

Such a light-emitting device including the covering member formed of an inorganic member still has room for improvement to improve the performance of the light-emitting device. The performance of the light-emitting device in the present specification is, for example, insulating properties, strength, or heat resistance.

An object of an embodiment of the present disclosure is to provide a method for manufacturing a light-emitting device with high performance.

A method for manufacturing a light-emitting device according to an embodiment of the present disclosure includes: disposing a plurality of light-emitting elements on a support, wherein each of the plurality of light emitting elements having an upper surface; disposing on the upper surfaces of the light-emitting elements and between adjacent light-emitting elements of the plurality of light-emitting elements an inorganic member having a void; forming a groove between the adjacent light-emitting elements in the inorganic member; and disposing a covering member on an upper surface of the inorganic member located above the light-emitting elements and in the groove to impregnate the void with a part of the covering member.

According to certain embodiments of the present disclosure, a light-emitting device with high performance can be manufactured.

### BRIEF DESCRIPTION OF DRAWINGS

FIG. 1 is a schematic cross-sectional view of a light-emitting device according to an embodiment of the present disclosure.

FIG. 2 is a partially enlarged schematic view of a cross section taken along line II-II in FIG. 1.

FIG. 3 is a partially enlarged schematic view of the cross section taken along line II-II in FIG. 1 in another example of the light-emitting device according to an embodiment of the present disclosure.

FIG. 4A is a schematic cross-sectional view (first) for explaining a method for manufacturing the light-emitting device according to an embodiment of the present disclosure.

FIG. 4B is a schematic cross-sectional view (second) for explaining the method for manufacturing the light-emitting device according to an embodiment of the present disclosure.

FIG. 4C is a partially enlarged schematic view of a cross section taken along line IV-IV in FIG. 4B.

FIG. 4D is a schematic cross-sectional view (third) for explaining the method for manufacturing the light-emitting device according to an embodiment of the present disclosure.

FIG. 4E is a schematic cross-sectional view (fourth) for explaining the method for manufacturing the light-emitting device according to an embodiment of the present disclosure.

FIG. 4F is a schematic cross-sectional view (fifth) for explaining the method for manufacturing the light-emitting device according to an embodiment of the present disclosure.

FIG. 4G is a schematic cross-sectional view (sixth) for explaining the method for manufacturing the light-emitting device according to an embodiment of the present disclosure.

FIG. 5 is a schematic cross-sectional view for explaining another example of a step of forming a groove.

FIG. 6A is a schematic cross-sectional view (first) for explaining another example of a method for manufacturing a light-emitting device according to an embodiment of the present disclosure.

FIG. 6B is a schematic cross-sectional view (second) for explaining another example of the method for manufacturing the light-emitting device according to an embodiment of the present disclosure.

FIG. 6C is a schematic cross-sectional view (third) for explaining another example of the method for manufacturing the light-emitting device according to an embodiment of the present disclosure.

FIG. 6D is a schematic cross-sectional view (fourth) for explaining another example of the method for manufacturing the light-emitting device according to an embodiment of the present disclosure.

FIG. 6E is a schematic cross-sectional view (fifth) for explaining another example of the method for manufacturing the light-emitting device according to an embodiment of the present disclosure.

FIG. 6F is a schematic cross-sectional view (sixth) for explaining another example of the method for manufacturing the light-emitting device according to an embodiment of the present disclosure.

### DETAILED DESCRIPTION

Hereinafter, certain embodiments of the present disclosure are described with reference to the drawings. Note that, in the following description, terms indicating specific directions or positions (for example, “upper”, “lower”, and other terms including those terms) are used as necessary. The use of those terms, however, is to facilitate understanding of the disclosure with reference to the drawings, and the technical scope of the present disclosure is not limited by the meanings of those terms. Parts having the same reference signs appearing in a plurality of drawings indicate identical or equivalent parts or members.

Further, the following embodiments exemplify light-emitting devices and the like for embodying the technical concept of the present disclosure, and the present disclosure is not limited to the description below. The dimensions, materials, shapes, relative arrangements, and the like of constituent components described below are not intended to limit the scope of the present disclosure to those alone, but are intended to provide an example, unless otherwise specified. The contents described in one embodiment can be applied to the other embodiment and modified examples. The sizes, positional relationship, and the like of the members illustrated in the drawings can be exaggerated in order to clarify the explanation. Further, in order to avoid excessive complication of the drawings, a schematic view in which some elements are not illustrated may be used, or an end view illustrating only a cutting surface may be used as a cross-sectional view.

### Method for Manufacturing Light-Emitting Device

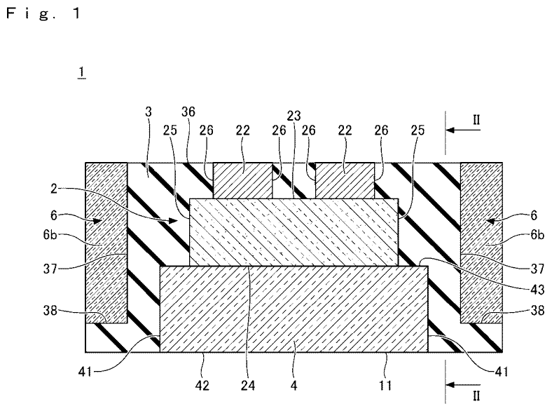

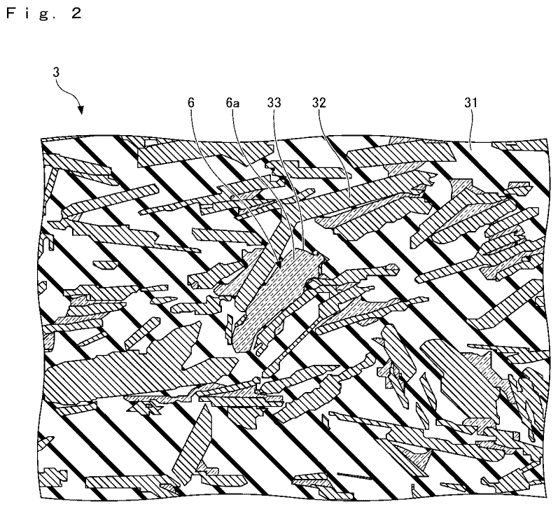

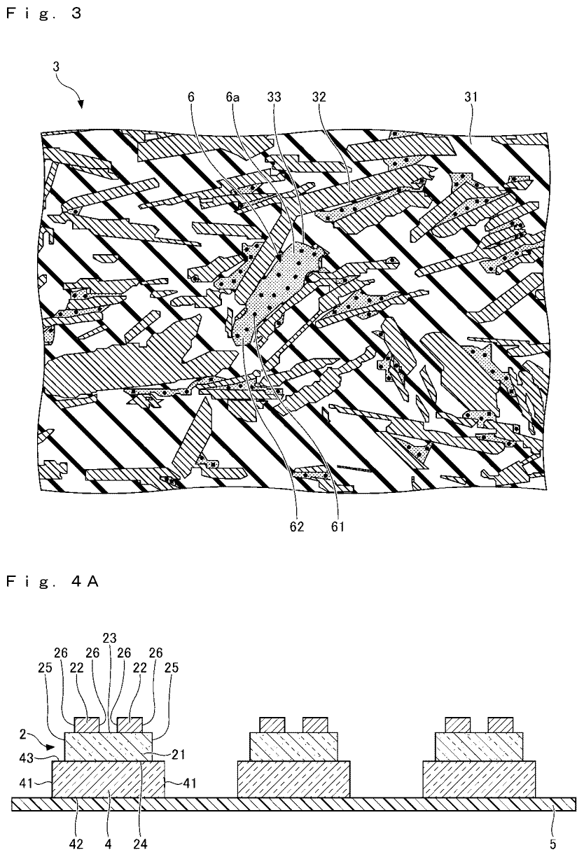

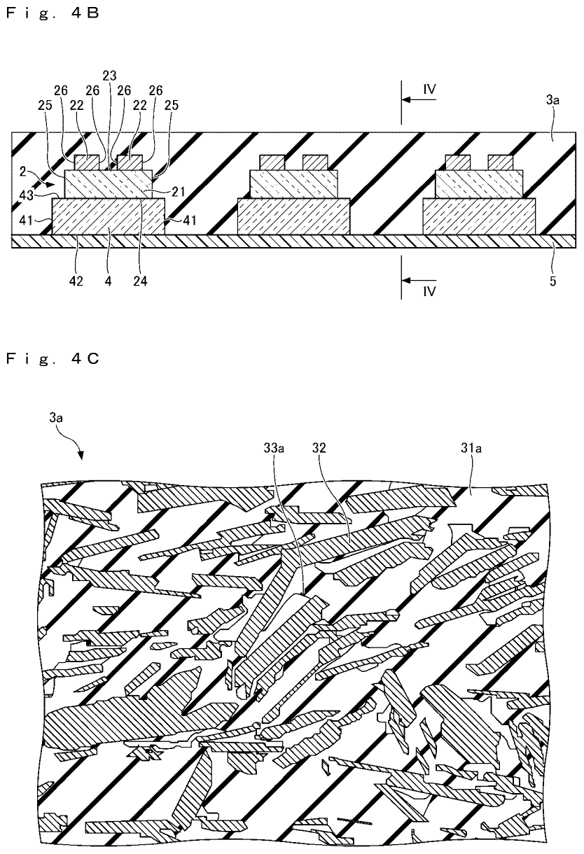

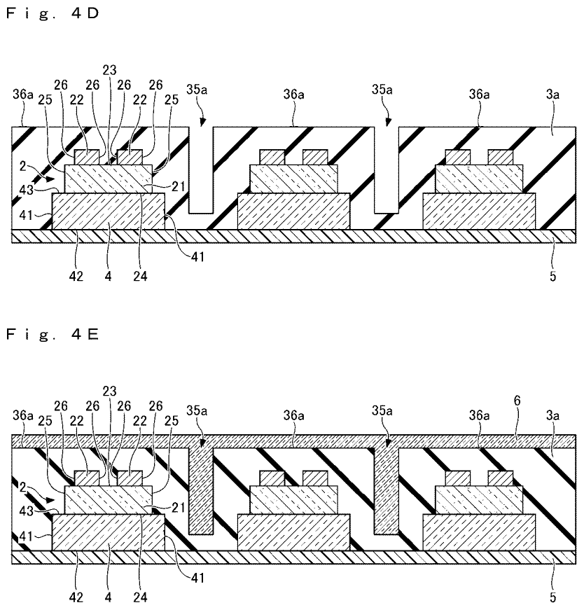

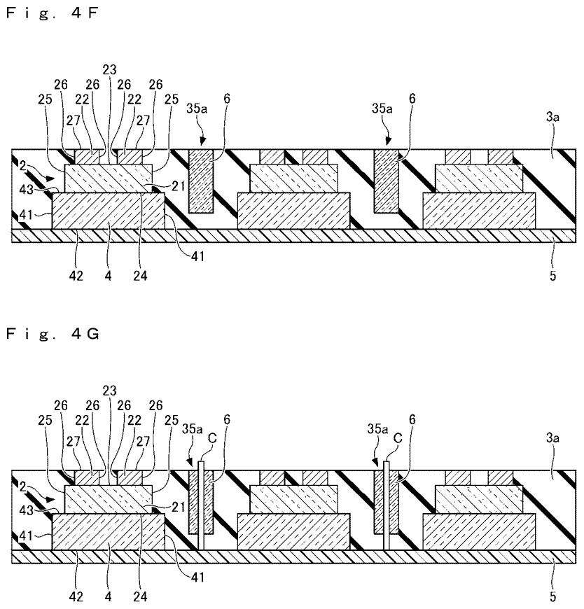

FIG. 1 is a schematic cross-sectional view of a light-emitting device 1 according to an embodiment, FIG. 2 is a partially enlarged schematic view of a cross section taken along line II-II in FIG. 1, FIGS. 4A, 4B, and 4D to 4G are schematic cross-sectional views for explaining a method for manufacturing the light-emitting device 1 according to an embodiment, and FIG. 4C is a partially enlarged schematic view of a cross section taken along line IV-IV in FIG. 4B. As illustrated in FIGS. 1 and 2, the light-emitting device 1 of the present embodiment includes a light-emitting element 2, an inorganic member 3 that covers an upper surface 23 and lateral surfaces 25 of the light-emitting element 2 and has pores 33, and a covering member 6 that covers the lateral surfaces of the inorganic member 3. The covering member 6 is disposed in the pores 33. An example of the method for manufacturing the light-emitting device 1 of the present embodiment is described below with reference to FIGS. 4A to 4G. In the present specification, when the pores 33 are hollow, the pores 33 may be referred to as “voids 33a”.

As illustrated in FIG. 4A, the method for manufacturing the light-emitting device 1 of the present embodiment includes a step of providing a plurality of light-emitting elements 2 each having an upper surface 23 and a lower surface 24 opposite to the upper surface 23, and a step of disposing the plurality of light-emitting elements 2 on a support 5. The method for manufacturing the light-emitting device 1 further includes a step of disposing an inorganic member 3a having the void 33a on the upper surfaces 23 of the light-emitting elements 2 and between adjacent ones of the light-emitting elements 2 as illustrated in FIGS. 4B and 4C, a step of forming a groove 35a between the adjacent light-emitting elements 2 in the inorganic member 3a as illustrated in FIG. 4D, and a step of disposing the covering member 6 on an upper surface 36a of the inorganic member 3a located above the light-emitting elements 2 and in the groove 35a to impregnate the void 33a with a part of the covering member 6 as illustrated in FIG. 4E.

The method for manufacturing the light-emitting device 1 described above allows for manufacturing the light-emitting device 1 of high performance. Details thereof are described below.

### Step of Providing Light-Emitting Element 2

The method for manufacturing the light-emitting device 1 of the present embodiment includes the step of providing the plurality of light-emitting elements 2 each having the upper surface 23 and the lower surface 24 opposite to the upper surface 23, as illustrated in FIG. 4A.

A semiconductor light-emitting element, such as a light-emitting diode (LED) chip or a semiconductor laser (LD) chip, can be preferably used for the light-emitting element 2. In the example illustrated in FIG. 4A, the light-emitting element 2 includes a semiconductor structure 21 and electrodes 22. In the example illustrated in FIG. 4A, positive and negative electrodes 22 are disposed on the upper surface 23 side of the light-emitting element 2. The light-emitting element 2 has the lateral surfaces 25 connecting the upper surface 23 and the lower surface 24. In the example illustrated in FIG. 4A, the upper surface 23, the lower surface 24, and the lateral surface 25 of the light-emitting element 2 are an upper surface, a lower surface, and a lateral surface of the semiconductor structure 21, respectively.

The semiconductor structure 21 includes an n-side semiconductor layer, a p-side semiconductor layer, and a light-emitting layer disposed between the n-side semiconductor layer and the p-side semiconductor layer. The light-emitting layer may have a single quantum well (SQW) structure, or may have a multi quantum well (MQW) structure including a plurality of well layers. The semiconductor structure 21 includes a plurality of semiconductor layers made of a nitride semiconductor. Examples of the nitride semiconductor include semiconductors having all compositions indicated by a chemical formula of InₓAl_{y}Ga_{1-x-y}N (0≤x, 0≤y, and x+y≤1), with various composition ratios x and y within respective ranges. The emission peak wavelength of the light-emitting layer can be selected as appropriate according to the purpose. The light-emitting layer is configured, for example, to emit visible light or ultraviolet light.

The light-emitting element 2 may or may not include a light-transmissive support substrate on the lower surface of the semiconductor structure 21. When the light-emitting element 2 includes the support substrate, a surface of the support substrate opposite to a surface opposed to the semiconductor structure 21 serves as the lower surface 24 of the light-emitting element 2.

The light-emitting element 2 may include a single semiconductor structure 21 provided on a primary surface of a single support substrate, or may include a plurality of the semiconductor structures 21 provided on a primary surface of a single support substrate. In addition, a single semiconductor structure 21 may include only one light-emitting layer or may include a plurality of the light-emitting layers. The structure of the semiconductor structure 21 including the plurality of light-emitting layers may be a structure including the plurality of light-emitting layers between a single n-side semiconductor layer and a single p-side semiconductor layer, or may be a structure in which the n-side semiconductor layer, the light-emitting layer, and the p-side semiconductor layer, in sequence, are repeated multiple times.

Examples of the material of the support substrate include a nitride semiconductor, such as sapphire, spinel (MgAl₂O₄), and gallium nitride.

The light-emitting element 2 can have any shape in plan view. The shape of the light-emitting element 2 in plan view is, for example, a quadrangle (that is, a square, a rectangle, or the like), a triangle, or a hexagon. When the shape of the light-emitting element 2 is a quadrangle in plan view, the size of the light-emitting element 2 can be, for example, 1 mm×1 mm. The term “plan view” in the present specification means a view from the upper surface 23 side of the light-emitting element 2.

### Step of Disposing a Plurality of Light-Emitting Elements 2

As illustrated in FIG. 4A, the method for manufacturing the light-emitting device 1 of the present embodiment includes the step of disposing the plurality of light-emitting elements 2 on the support 5. As the support 5, an adhesive sheet such as polyimide can be used. In the example illustrated in FIG. 4A, the light-emitting elements 2 are disposed on the support 5 such that the lower surfaces 24 of the light-emitting elements 2 (that is, surfaces of the light-emitting elements 2 on which the electrodes 22 are not disposed) face the support 5. Thus, lateral surfaces 26 of the electrodes 22 are easily covered with the inorganic member 3a in the step of disposing the inorganic member 3a to be described below. In the example illustrated in FIG. 4A, light-transmissive members 4 are disposed between the support 5 and the light-emitting elements 2, each of the light-transmissive members 4 being disposed on the lower surface 24 of a respective one of the plurality of light-emitting elements 2. Such a configuration is obtained by, for example, disposing the light-transmissive members 4 on the support 5 and disposing each of the light-emitting elements 2 on an upper surface 43 of a respective one of the light-transmissive members 4, in the step of disposing the plurality of light-emitting elements 2. Alternatively, such a configuration is obtained by disposing each of the light-emitting elements 2 on a respective one of the light-transmissive members 4 and disposing layered bodies of the light-transmissive member 4 and the light-emitting element 2 on the support 5.

The light-transmissive member 4 can contain a wavelength conversion material that can convert a wavelength of at least a part of light from the light-emitting element 2. This facilitates chromaticity adjustment of the light-emitting device 1 manufactured by the manufacturing method according to the present embodiment. The wavelength conversion material contained in the light-transmissive member 4 may be of one type or a plurality of types.

The light-transmissive member 4 may be formed of the wavelength conversion material and a base material, or may be formed of only the wavelength conversion material. In addition, the light-transmissive member 4 may have a configuration in which the wavelength conversion member is used as a base material and an inorganic material and/or a light-diffusing material to be described below is included.

When the light-transmissive member 4 is formed of the wavelength conversion material and the base material, the wavelength conversion material may be contained in the base material or may be disposed on the surface of the base material. When the wavelength conversion material is disposed on the surface of the base material, the wavelength conversion material can be disposed on a surface of the base material facing the light-emitting element 2. A structure may be employed in which only the wavelength conversion material is disposed on a surface of the base material, or in which a resin containing the wavelength conversion material is disposed on the surface of the base material.

When the wavelength conversion material is contained in the base material, the wavelength conversion material may be dispersed in the base material or may be unevenly distributed in the base material.

Examples of the material of the base material include an inorganic material, such as glass, ceramic, or sapphire, and an organic material, such as a resin or a hybrid resin containing one or more kinds of silicone resins, modified silicone resins, epoxy resins, modified epoxy resins, acrylic resins, phenol resins, and fluorine resins.

As the wavelength conversion material, a known phosphor can be used. For example, as the phosphor, an yttrium aluminum garnet-based phosphor (for example, (Y, Gd)₃(Al, Ga)₅O₁₂:Ce), a lutetium aluminum garnet-based phosphor (for example, Lu₃(Al, Ga)₅O₁₂:Ce), a terbium aluminum garnet-based phosphor (for example, Tb₃(Al, Ga)₅O₁₂:Ce), a CCA-based phosphor (for example, Ca₁₀(PO₄)₆Cl₂:Eu), an SAE-based phosphor (for example, Sr₄Al₁₄O₂₅:Eu), a chlorosilicate-based phosphor (for example, Ca₈MgSi₄O₁₆Cl₂:Eu), a silicate-based phosphor (for example, (Ba, Sr, Ca, Mg)₂SiO₄:Eu), oxynitride-based phosphors, such as a β-SiAlON-based phosphor (for example, (Si, Al)₃(O,N)₄:Eu) and an α-SiAlON-based phosphor (for example, Ca(Si, Al)₁₂(O,N)₁₆:Eu), nitride-based phosphors, such as an LSN-based phosphor (for example, (La, Y)₃Si₆N₁₁:Ce), a BSESN-based phosphor (for example, (Ba, Sr)₂Si₅N₈:Eu), an SLA-based phosphor (for example, SrLiAl₃N₄:Eu), a CASN-based phosphor (for example, CaAlSiN₃:Eu), and an SCASN-based phosphor (for example, (Sr, Ca)AlSiN₃:Eu), fluoride-based phosphors, such as a KSF-based phosphor (for example, K₂SiF₆:Mn), a KSAF-based phosphor (for example, K₂(Si₁₋ₓAlₓ)F₆₋ₓ:Mn, where x satisfies 0<x<1), and an MGF-based phosphor (for example, 3.5 MgO·0.5MgF₂·GeO₂:Mn), a quantum dot having a perovskite structure (for example, (Cs, FA, MA)(Pb, Sn)(F, Cl, Br, I)₃, where FA and MA represent formamidinium and methylammonium, respectively), a II-VI group quantum dot (for example, CdSe), a III-V group quantum dot (for example, InP), a quantum dot having a chalcopyrite structure (for example, (Ag, Cu)(In, Ga)(S, Se)₂), or the like can be used.

The light-transmissive member 4 can contain a light-diffusing material according to purpose. A light-diffusing material known in the art can be employed for the light-diffusing material. Examples of the light-diffusing material that can be used include titanium oxide, silicon oxide, aluminum oxide, barium titanate, and yttrium aluminum perovskite (YAP).

### Step of Disposing Inorganic Member 3a

As illustrated in FIGS. 4B and 4C, the method for manufacturing the light-emitting device 1 of the present embodiment includes the step of disposing the inorganic member 3a having the void 33a on the upper surfaces 23 of the light-emitting elements 2 and between adjacent light-emitting elements 2. When a respective one of the light-transmissive members 4 is disposed between the support 5 and a corresponding one of the light-emitting elements 2 and is disposed on the lower surface 24 of the corresponding one of the plurality of light-emitting elements 2 in the step of disposing the plurality of light-emitting elements 2, the inorganic member 3a is further disposed on lateral surfaces 41 of the respective one of the light-transmissive members 4 in the step of disposing the inorganic member 3a.

The inorganic member 3a is, for example, a light-reflective member containing a light-reflective material 32, silicon dioxide, and an alkali metal.

When the inorganic member 3a is formed of the light-reflective member containing the light-reflective material 32, silicon dioxide, and the alkali metal, the step of disposing the inorganic member 3a includes mixing powder of the light-reflective material 32, powder of the silicon dioxide, and an alkali metal aqueous solution to prepare a mixture, and applying the mixture, and a step of heating the mixture.

In the preparing of the mixture, the concentration of the alkali metal aqueous solution is preferably 1 mol/L or more, for example, from the viewpoint of ease of curing and strength after curing. On the other hand, the concentration is preferably 5 mol/L or less from the viewpoint of reducing precipitation of an excessive alkali metal after mixing. The alkali metal aqueous solution is a potassium hydroxide solution or a sodium hydroxide solution, for example. In the preparing of the mixture, for example, after performing mixing to obtain a mixed powder, defoaming and stirring are performed by a stirring-defoaming machine that can perform stirring under reduced pressure.

In the step of applying the mixture, the mixture is applied from above the light-emitting elements 2 to cover the upper surface of the support 5, the lateral surfaces 25 of the light-emitting elements 2, and the upper surfaces 23 of the light-emitting elements 2. When each of the light-transmissive members 4 is disposed between a corresponding one of the light-emitting elements 2 and the support 5, the mixture covers the lateral surfaces 41 of the light-transmissive members 4 and a region of the upper surface 43 of each of the light-transmissive members 4 where no light-emitting element 2 is disposed.

In the step of heating the mixture, the mixture is cured by heating the mixture, and thus the inorganic member 3a is formed. The inorganic member 3a contains an alkali metal silicate produced by a reaction between the silicon dioxide and the alkali metal aqueous solution contained in the mixture. Examples of the alkali metal silicate include potassium silicate, sodium silicate, and lithium metasilicate. The step of heating the mixture includes, for example, a temporary curing in which the mixture is heated and cured at a first temperature T1 and a main curing in which the mixture is heated and cured at a second temperature T2 higher than the first temperature T1. In the temporary curing, heating is performed at the first temperature T1 in a range from 80° C. to 100° C. in a range from 10 minutes to 2 hours, for example. The main curing step performs heating at the second temperature T2 in a range from 150° C. to 250° C. in a range from 10 minutes to 3 hours, for example.

The light-reflective material 32 can reflect light emitted from the light-emitting elements 2. The light-reflective material 32 contains, for example, at least one selected from boron nitride, aluminum nitride, or aluminum oxide. Because boron nitride, aluminum nitride, and aluminum oxide are materials having good thermal conductivity, the inorganic member 3a with a good heat dissipation property can be obtained. The covering member 6 includes a plurality of light-reflective materials 32, and at least some of the plurality of light-reflective materials 32 are in contact with each other. This can reduce the shrinkage of the inorganic member 3a formed by heating and curing the mixture. The inorganic member 3a may further contain other particles of zirconium oxide, titanium oxide, or the like.

The light-reflective material 32 is, for example, a plate-shaped (including scale-like shape) particle having two main surfaces. The light-reflective material 32 may be a primary particle, or a secondary particle in which two or more primary particles are aggregated. In addition, the light-reflective material 32 may be a mixture of a primary particle and a secondary particle.

An average aspect ratio of the primary particles of the light-reflective materials 32 is preferably 10 or more, more preferably in a range from 10 to 70. When the light-reflective materials 32 are boron nitride, the average aspect ratio of the light-reflective materials 32 is in a range from 16.5 to 19.2, for example. When the light-reflective materials 32 are aluminum oxide, the average aspect ratio of the light-reflective materials 32 is in a range from 10 to 70, for example. The average aspect ratio of the light-reflective materials 32 can be calculated by the following method, for example.

### Calculation Method of Average Aspect Ratio

The average aspect ratio of the light-reflective materials 32 is calculated through measuring lengths of major axes and lengths of minor axes of the light-reflective materials 32 included in the inorganic member 3a in a cross section of the inorganic member 3a after the inorganic member 3a is disposed. First, a cross section that passes through the center of the upper surface 23 of the light-emitting element 2 and is substantially orthogonal to the upper surface 23 is exposed. Subsequently, the exposed cross section is mirror polished. The mirror-polished cross section is observed with a scanning electron microscope (SEM) at a magnification in a range from 2000× power to 3000× power, the cross sections of the light-reflective materials 32 are extracted from the obtained image, and a measurement region including cross sections of approximately 1000 light-reflective materials 32 is selected. The average aspect ratio of the light-reflective materials 32 can also be calculated through measuring the lengths of the major axes and the lengths of the minor axes of the light-reflective materials 32 included in the inorganic member 3 in the cross section of the light-emitting device 1 after the light-emitting device 1 is manufactured.

Subsequently, with image analysis software, the length of the major axis and length of the minor axis of each extracted cross section of the light-reflective material 32 are measured to calculate a ratio (the aspect ratio) of the length of the major axis to the length of the minor axis. Subsequently, the average value of aspect ratios of 100 light-reflective materials 32 is set as the average aspect ratio.

The average particle diameter of the light-reflective materials 32 is preferably in a range from 0.6 μm to 43 μm. When the light-reflective materials 32 are boron nitride, the average particle diameter of the light-reflective materials 32 is in a range from 6 μm to 43 μm, for example. When the light-reflective materials 32 are aluminum oxide, the average particle diameter of the light-reflective materials 32 is in a range from 0.6 μm to 10 μm, for example.

The light-reflective materials 32 due to the manufacturing process is slight, so that the shape and dimensions of the powder of the light-reflective materials 32 are substantially the same as the shape and dimensions of the light-reflective materials 32 included in the inorganic member 3a or 3. Therefore, the average particle diameter of the light-reflective materials 32 can be calculated by the following method, for example.

### Calculation Method of Average Particle Diameter

The particle diameters of the powder of the light-reflective materials 32 are calculated using a scanning electron microscope “TM3030Plus” manufactured by Hitachi High-Tech Corporation, for example. First, one surface of a double-sided tape made of carbon is attached to a sample stage of the microscope, and then the powder of the light-reflective materials 32 is disposed on the other surface of the double-sided tape. The magnification of the microscope is set in a range from 1000× power to 2000× power to acquire images of the powder (particles) of 100 light-reflective materials 32. Subsequently, the particle diameter of each particle is measured with the image analysis software.

In the present specification, the particle diameter of the powder of the light-reflective material 32 means a maximum diameter among the diameters when viewed from one main surface of the light-reflective material 32. Subsequently, a median diameter of the measured particles is calculated, and the calculated value is set as the average particle diameter of the light-reflective materials 32. The particle diameters of the powder of the light-reflective materials 32 may be calculated by extracting the cross section of the inorganic member 3a with the SEM and performing measurement with the image analysis software. The average particle diameter of the light-reflective materials 32 can also be calculated by extracting the cross section of the inorganic member 3 with the SEM after the light-emitting device 1 is manufactured and performing measurement with the image analysis software.

The weight ratio between the powder of the silicon dioxide and the powder of the light-reflective materials 32 is in a range from 1:4 to 1:1, for example. That is, for the powder of the silicon dioxide and the powder of the light-reflective materials 32, the weight of the powder of the light-reflective material 32 is in a range from one time to four times the weight of the powder of the silicon dioxide, for example. The weight ratio between the alkali metal aqueous solution and the mixed powder is in a range from 2:10 to 8:10, for example. That is, for the alkali metal aqueous solution and the mixed powder, the weight of the mixed powder is in a range from 1.25 times to 5 times the weight of the alkali metal aqueous solution. When the weight of the alkali metal aqueous solution is much smaller than the weight of the mixed powder, multiple fine lumps are formed at the time of mixing the mixed powder and the alkali metal aqueous solution, making formation difficult. On the other hand, when the weight of the alkali metal aqueous solution is much larger than the weight of the mixed powder, cracks may occur when the mixture is heated and cured, and the strength of the inorganic member 3a obtained through curing may decrease.

The inorganic member 3a having the void 33a includes, for example, the light-reflective material 32 and a support member 31a supporting the light-reflective material 32 as illustrated in FIG. 4C. The void 33a is formed in the support member 31a, for example, in the curing step. The support member 31a includes silicon dioxide and an alkali metal. With the support member 31a formed of an inorganic material, the support member 31a has heat resistance to heat from the light-emitting elements 2 and the light-transmissive members 4.

### Step of Forming Groove 35a

As illustrated in FIG. 4D, the method for manufacturing the light-emitting device 1 of the present embodiment includes the step of forming the groove 35a between adjacent light-emitting elements 2 in the inorganic member 3a. Thus, in the step of impregnation to be described below, the void 33a of the inorganic member 3a can be impregnated with the covering member 6 from both the upper surface 36a of the inorganic member 3a and the groove 35a, so that the entire inorganic member 3a can be efficiently impregnated with the covering member 6. The groove 35a opens toward the upper surface 23 side of the light-emitting element 2.

The shape of the groove 35a in cross-sectional view is a quadrangular shape defined by its bottom surface and lateral surfaces orthogonal to each other in the example illustrated in FIG. 4D. The shape of the groove 35a in cross-sectional view is not limited to the above-described shape, and the lateral surface of the groove 35a may be inclined with respect to the bottom surface of the groove 35a. The bottom surface of the groove 35a may be a flat surface or a curved surface recessed toward the support 5. The shape of the groove 35a in cross-sectional view may also be a shape without having a bottom surface, in which lower ends of inclined lateral surfaces are in contact with each other (that is, a V shape).

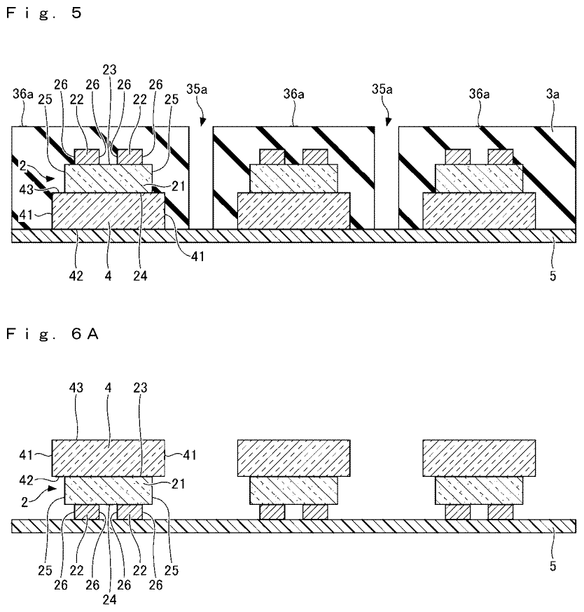

FIG. 5 is a schematic cross-sectional view for explaining another example of the step of forming the groove 35a. In the example illustrated in FIG. 4D, the groove 35a does not penetrate the inorganic member 3a. However, the present disclosure is not limited thereto, and in the step of forming the groove 35a, the groove 35a may penetrate the inorganic member 3a as illustrated in FIG. 5. In the step of forming the groove 35a, with the groove 35a penetrating the inorganic member 3a, in the step of impregnation to be described below, an area of the covering member 6 in contact with the inorganic member 3a can be increased and the entire inorganic member 3a can be efficiently impregnated with the covering member 6.

### Step of Impregnation

As illustrated in FIG. 4E, the method for manufacturing the light-emitting device 1 of the present embodiment includes the step of disposing the covering member 6 on the upper surface 36a located above the light-emitting elements 2 and in the groove 35a in the inorganic member 3a to impregnate the void 33a with a part of the covering member 6.

By impregnating the void 33a with a part of the covering member 6, the light-emitting device 1 including the inorganic member 3a with high insulating properties can be manufactured. The reason is considered as follows. When the void 33a is impregnated with the covering member 6, since the likelihood of entry of moisture present in the atmosphere into the pores 33 can be reduced, a reaction between the alkali metal silicate contained in the inorganic member 3a and the moisture can be reduced. Thus, generation of metal ions derived from the alkali metal silicate can be reduced, so that generation of leakage current can be reduced.

Further, with the covering member 6 disposed both on the upper surface 36a located above the light-emitting elements 2 in the inorganic member 3a and in the groove 35a, the void 33a of the inorganic member 3a can be impregnated with the covering member 6 from both the upper surface 36a of the inorganic member 3a and the groove 35a and the entire inorganic member 3a can be efficiently impregnated with the covering member 6. By impregnating the void 33a with a part of the covering member 6, the light-emitting device 1 including the inorganic member 3a with a high mechanical strength can be manufactured.

The void 33a of the inorganic member 3a is open on the surface of the inorganic member 3a. When the covering member 6 is disposed on the upper surface 36a of the inorganic member and in the groove 35a, the inorganic member 3a is impregnated with the covering member 6 from the opening of the void 33a located on the upper surface 36a of the inorganic member 3a and a surface of the groove 35a. In the step of impregnation, the entire void 33a of the inorganic member 3a is preferably impregnated with the covering member 6. Thus, the mechanical strength of the entire inorganic member 3a can be increased.

As a method of disposing the covering member 6, the covering member 6 may be applied to the upper surface 36a of the inorganic member and the groove 35a of the inorganic member 3a from the upper surface 23 side with respect to the light-emitting elements 2, or the covering member 6 may be impregnated with the inorganic member 3a.

In the step of impregnation with the covering member 6, the covering member 6 can completely fill the groove 35a. This increases the thickness of the covering member 6 in the direction orthogonal to the surface of the groove 35a, and thus the method for manufacturing the light-emitting device 1 allows manufacture of the light-emitting device 1 including the inorganic member 3a with a high mechanical strength. In the step of disposing the covering member 6, the covering member 6 need not completely fill the groove 35a. For example, the covering member 6 may be disposed in the form of a thin film on the surface of the groove 35a.

In the step of disposing the covering member 6, examples of the covering member 6 include a mixture containing polysilazane and a solvent, and a mixture containing inorganic particles of silicon dioxide, aluminum oxide, or the like and a solvent. The inorganic particles have a size small enough to pass through the pores 33. The solvent can be used to facilitate the impregnation with the covering member 6. Examples of the solvent include alcohol and dibutyl ether. After the void 33a of the inorganic member 3a is impregnated with the covering member 6, the covering member 6 can be heated. By heating the covering member 6, the solvent contained in the covering member 6 can be volatilized. When the covering member 6 contains polysilazane, glass containing silicon dioxide is formed by heating the covering member 6.

### Step of Exposing Electrodes 22

As illustrated in FIG. 4F, the method for manufacturing the light-emitting device 1 of the present embodiment may include, after the step of impregnation, a step of removing the inorganic member 3a and the covering member 6 located above the upper surfaces 23 of the light-emitting elements 2 to expose the electrodes 22 by. Specifically, in the step of exposing the electrodes 22, the inorganic member 3a and the covering member 6 located above the upper surfaces 23 of the light-emitting elements 2 can be removed by grinding. This can manufacture the light-emitting device 1 in which upper surfaces 27 of the electrodes 22 are exposed and the lateral surfaces 26 are covered with the inorganic member 3a. According to the method for manufacturing the light-emitting device 1, the void 33a is impregnated with the covering member 6, so that, in the step of exposing the electrodes 22, the likelihood of chipping or the like of the covering member 6 due to grinding can be reduced and the electrodes 22 can be exposed with high processing accuracy as compared with a case in which the void 33a is not impregnated with the covering member 6.

In the step of exposing the electrodes 22, the inorganic member 3a and the covering member 6 located above the upper surfaces 23 of the light-emitting elements 2 may be removed by etching.

### Step of Cutting

As illustrated in FIG. 4G, the method for manufacturing the light-emitting device 1 of the present embodiment may include a step of cutting the inorganic member 3a and the covering member 6 at a position corresponding to the groove 35a after the step of impregnation. This can manufacture the light-emitting device 1 in which the covering member 6 is disposed on both lateral surfaces of the inorganic member 3a. In the step of cutting, the inorganic member 3a and the covering member 6 are preferably cut by using a blade C having a width narrower than a width of the groove 35a. Thus, a thickness of a portion of the covering member 6 covering the lateral surfaces of the inorganic member 3a can be increased, so that the light-emitting device 1 including the inorganic member 3a with a high mechanical strength can be manufactured. When the groove 35a does not penetrate the inorganic member 3a, the void 33a of the inorganic member 3a located below the groove 35a is impregnated with the covering member 6, so that the likelihood of chipping or the like of the covering member 6 due to cutting can be reduced and the inorganic member 3a and the covering member 6 can be cut with high processing accuracy as compared with a case in which the void 33a is not impregnated with the covering member 6.

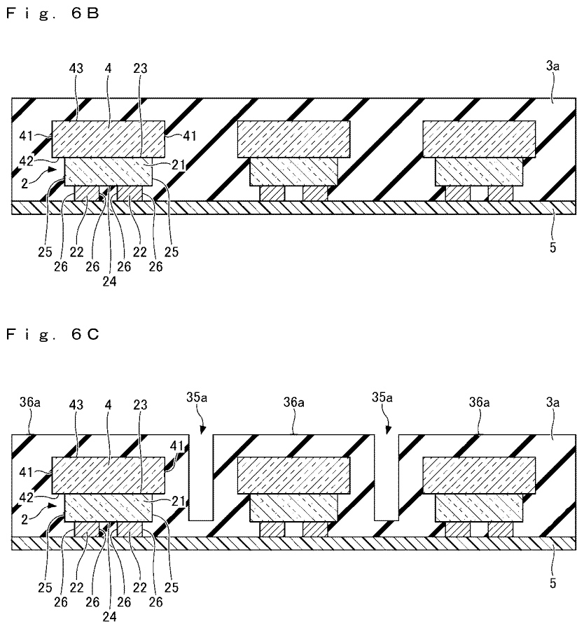

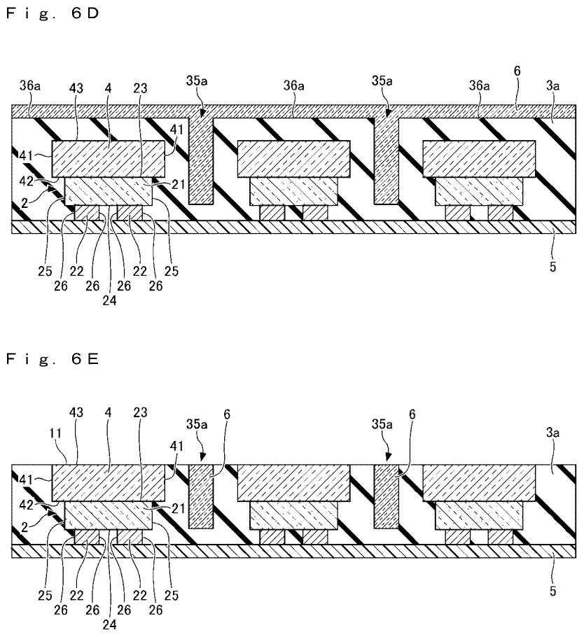

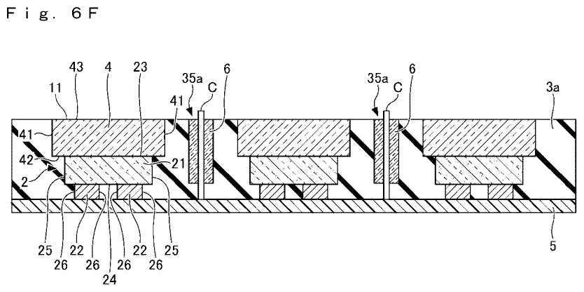

FIGS. 6A to 6F are schematic cross-sectional views for explaining another example of the method for manufacturing the light-emitting device 1 according to an embodiment. The method for manufacturing the light-emitting device 1 of the present embodiment is different from the method for manufacturing the light-emitting device 1 illustrated in FIGS. 4A to 4G in that positive and negative electrodes 22 are disposed on the lower surface 24 side of each of the light-emitting elements 2 and the light-emitting elements 2 are disposed on the support 5 such that the lower surfaces 24 of the light-emitting elements 2 (that is, the surfaces of the light-emitting elements 2 on which the electrodes 22 are disposed) face the support 5.

As illustrated in FIG. 6A, the method for manufacturing the light-emitting device 1 of the present embodiment includes a step of providing the plurality of light-emitting elements 2 each having the upper surface 23 and the lower surface 24 opposite to the upper surface 23, and a step of disposing the plurality of light-emitting elements 2 on the support 5. The method for manufacturing the light-emitting device 1 further includes a step of disposing the inorganic member 3a having the void 33a on the upper surfaces 23 of the light-emitting elements 2 and between adjacent ones of the light-emitting elements 2 as illustrated in FIG. 6B, a step of forming the groove 35a between the adjacent light-emitting elements 2 in the inorganic member 3a as illustrated in FIG. 6C, and a step of disposing the covering member 6 on the upper surface 36a of the inorganic member 3a located above the light-emitting elements 2 and in the groove 35a and impregnating the void 33a with a part of the covering member 6 as illustrated in FIG. 6D. Since the step of disposing the inorganic member 3a, the step of forming the groove 35a, the step of impregnation, and the step of cutting are the same as those in the method for manufacturing the light-emitting device 1 illustrated in FIGS. 4A to 4G, the description thereof is omitted here.

### Step of Providing Light-Emitting Element 2

As illustrated in FIG. 6A, the method for manufacturing the light-emitting device 1 of the present embodiment includes the step of providing the plurality of light-emitting elements 2 each having the upper surface 23 and the lower surface 24 opposite to the upper surface 23. In the example illustrated in FIG. 6A, the positive and negative electrodes 22 are disposed on the lower surface 24 side of the light-emitting element 2. Since the other steps are the same as those of the method for manufacturing the light-emitting device 1 illustrated in FIG. 4A, the description thereof is omitted here.

### Step of Disposing Plurality of Light-Emitting Elements 2

The method for manufacturing the light-emitting device 1 of the present embodiment includes a step of disposing the plurality of light-emitting elements 2 on the support 5, as illustrated in FIG. 6A. As the support 5, a wiring substrate or an adhesive sheet of polyimide or the like can be used. In the example illustrated in FIG. 6A, the light-emitting elements 2 are disposed on the support 5 such that the lower surfaces 24 of the light-emitting elements 2 face the support 5. In the example illustrated in FIG. 6A, the light-transmissive member 4 is disposed on the upper surface 23 of each of the plurality of light-emitting elements 2 in the step of disposing the plurality of light-emitting elements 2. However, the present disclosure is not limited thereto and the light-transmissive member 4 need not be disposed on the upper surface 23 of every light-emitting element 2, or need not be disposed on the upper surface 23 of part of the plurality of light-emitting elements 2.

### Step of Exposing Light-Emitting Surfaces 11

As illustrated in FIG. 6E, the method for manufacturing the light-emitting device 1 of the present embodiment may include a step of exposing the light-emitting surfaces 11 by removing the inorganic member 3a and the covering member 6 located above the upper surface 43 of the light-transmissive members 4 after the step of disposing the covering member 6. The light-emitting surface 11 is the upper surface 43 of the light-transmissive member 4, and is a surface from which light is emitted in the light-emitting device 1. When the light-transmissive member 4 is disposed on the upper surface 23 of each of the plurality of light-emitting elements 2 in the step of disposing the plurality of light-emitting elements 2, the light-emitting surface 11 can be exposed by removing the inorganic member 3a and the covering member 6 located above the upper surfaces 43 of the light-transmissive members 4 in the step of exposing the light-emitting surfaces 11. Specifically, in the step of exposing the light-emitting surfaces 11, the inorganic member 3a and the covering member 6 located above the upper surfaces 43 of the light-transmissive members 4 can be removed by grinding.

When the light-transmissive member 4 is not disposed on the upper surface 23 of each of the plurality of light-emitting elements 2 in the step of disposing the plurality of light-emitting elements 2, the light-emitting surfaces 11 (that is, the upper surfaces 23 of the light-emitting elements 2) can be exposed by removing the inorganic member 3a and the covering member 6 located above the upper surfaces 23 of the light-emitting elements 2 in the step of exposing the light-emitting surfaces 11.

The method for manufacturing the light-emitting device 1 illustrated in FIGS. 6A to 6F also achieves the same effects as the method for manufacturing the light-emitting device 1 illustrated in FIGS. 4A to 4G. Thus, with the method for manufacturing the light-emitting device 1 illustrated in FIGS. 6A to 6F, the light-emitting device 1 with high performance can be manufactured.

### Light-Emitting Device

As illustrated in FIGS. 1 and 2, the light-emitting device 1 includes the light-emitting element 2, the inorganic member 3 that covers the upper surface 23 and the lateral surfaces 25 of the light-emitting element 2 and having the pores 33, and the covering member 6 that covers the inorganic member 3. The covering member 6 is disposed in the pores 33. With this configuration, the light-emitting device 1 includes the inorganic member 3a having a mechanical strength higher than that in a light-emitting device in which the covering member 6 is not disposed in the pores 33. Further, with the covering member 6 disposed in the pores 33, the light-emitting device 1 includes the inorganic member 3a having high insulating properties. Thus, the light-emitting device 1 with high performance can be provided.

The light-emitting element 2 is the same as the light-emitting element 2 in the method for manufacturing the light-emitting device 1, and accordingly the description thereof is omitted here.

The inorganic member 3 is further disposed on the lateral surfaces 26 of the electrodes 22 disposed on the upper surface 23 of the light-emitting element 2. In the example illustrated in FIG. 2, the inorganic member 3 includes a light-reflective material 32, and a support member 31 that supports the light-reflective material 32. The support member 31 contains silicon dioxide and an alkali metal. The light-reflective material 32 is the same as the light-reflective material 32 in the method for manufacturing the light-emitting device 1, and accordingly the description thereof is omitted here. The inorganic member 3 contains an alkali metal silicate produced by a reaction between the silicon dioxide and the alkali metal silicate. Examples of the alkali metal silicate include potassium silicate, sodium silicate, and lithium metasilicate.

The covering member 6 includes a first portion 6a located in the pores 33 and a second portion 6b located on a lateral surface 37 of the inorganic member 3. Including the second portion 6b disposed on the lateral surface 37 of the inorganic member 3 allows for reducing the impact of external force applied to the light-emitting device 1 from the outside. In the example illustrated in FIG. 1, the covering member 6 includes the second portion 6b disposed on the lateral surface 37 and a bottom surface 38 of the inorganic member 3.

The covering member 6 is formed of, for example, a mixture containing polysilazane and a solvent. In a case in which the covering member 6 is formed of a mixture containing polysilazane and a solvent, when the polysilazane contained in the covering member 6 is heated, glass containing silicon dioxide is formed. In the example illustrated in FIG. 2, glass and a solvent are disposed in the pores 33, as the covering member 6. A structure may be employed in which only glass is disposed in the pores 33.

FIG. 3 is a partially enlarged schematic view of a cross section taken along line II-II in FIG. 1 in another example of the light-emitting device according to an embodiment. The covering member 6 can be formed of a mixture containing inorganic particles of silicon dioxide, aluminum oxide, or the like, and a solvent. When the covering member 6 is formed of a mixture containing inorganic particles and a solvent, inorganic particles 61 and a solvent 62 are disposed in the pores 33, as the covering member 6, as illustrated in FIG. 3. Note that the covering member 6 may be formed of only the inorganic particles 61.

In the example illustrated in FIG. 1, the light-emitting device 1 includes the light-transmissive member 4 disposed on the lower surface 24 of the light-emitting element 2. The inorganic member 3 covers the lateral surfaces 41 of the light-transmissive member 4. A lower surface 42 of the light-transmissive member 4 exposed from the inorganic member 3 is the light-emitting surface 11 of the light-emitting device 1.

The light-transmissive member 4 may be disposed on the lower surface 24 of the light-emitting element 2 via an adhesive, or may be directly disposed on the lower surface 24 without an adhesive.

In the example illustrated in FIG. 1, the light-emitting device 1 includes the light-transmissive member 4. However, the present disclosure is not limited thereto and the light-emitting device 1 need not include the light-transmissive member 4. When the light-emitting device 1 does not include the light-transmissive member 4, the lower surface 24 of the light-emitting element 2 serves as the light-emitting surface 11 of the light-emitting device 1.

Since the details of the light-transmissive member 4 are as described above, the description thereof is omitted here.

In the example illustrated in FIG. 1, the light-emitting device 1 does not include a wiring substrate. However, the present disclosure is not limited thereto, and the light-emitting device 1 may include a wiring substrate. When the light-emitting device 1 includes a wiring substrate, the electrode 22 of the light-emitting element 2 is electrically connected to the wiring of the wiring substrate. In addition, on the surface of the wiring substrate opposed to the light-emitting element 2, the inorganic member 3 can be disposed in a region other than the region electrically connected to the electrodes 22 of the light-emitting element 2. Further, a single light-emitting element 2 may be electrically connected to a single wiring substrate, or a plurality of light-emitting elements 2 may be electrically connected to a single wiring substrate. As a base material of the wiring substrate, aluminum nitride can be used, for example.

What is claimed is:

1. A method for manufacturing a light-emitting device, comprising:
disposing a plurality of light-emitting elements on a support, wherein each of the plurality of light emitting elements having an upper surface;
disposing on the upper surfaces of the light-emitting elements and between adjacent light-emitting elements of the plurality of light-emitting elements an inorganic member having a void;
forming a groove between the adjacent light-emitting elements in the inorganic member; and
disposing a covering member on an upper surface of the inorganic member located above the light-emitting elements and in the groove to impregnate the void with a part of the covering member.

2. The method for manufacturing a light-emitting device, according to claim 1, wherein in the forming of the groove, the groove penetrates the inorganic member.

3. The method for manufacturing a light-emitting device, according to claim 1, further comprising:
after the disposing of the covering member, cutting the inorganic member and the covering member at a position corresponding to the groove.

4. The method for manufacturing a light-emitting device, according to claim 3, wherein, in the cutting of the inorganic member and the covering member, the inorganic member and the covering member are cut by using a blade having a width narrower than a width of the groove.

5. The method for manufacturing a light-emitting device according to claim 1, wherein the light-emitting elements each comprise, on the upper surfaces thereof, positive and negative electrodes, and
the method further comprises, after the disposing of the covering member, exposing the electrodes by removing a portion of the inorganic member and a portion of the covering member that are located above the upper surfaces of the light-emitting elements.

6. The method for manufacturing a light-emitting device according to claim 5, wherein, in the exposing of the electrodes, the portion of the inorganic member and the portion of the covering member that are located above the upper surfaces of the light-emitting elements are removed by grinding.

7. The method for manufacturing a light-emitting device according to claim 1, wherein, in the disposing of the covering member, the covering member is a mixture containing polysilazane and a solvent.

8. The method for manufacturing a light-emitting device according to claim 1, wherein, in the disposing of the covering member, the covering member is a mixture containing an inorganic particle and a solvent.

9. The method for manufacturing a light-emitting device according to claim 1, wherein the inorganic member is a light-reflective member comprising a light-reflective material, silicon dioxide, and an alkali metal.
